(19) United States
(12) Patent Application Publication
(10) Pub. No.: US 2026/0075923 A1
(43) Pub. Date: Mar. 12, 2026

(54) SEMICONDUCTOR APPARATUS

(71) Applicants: KABUSHIKI KAISHA TOSHIBA, Kawasaki-shi (JP); Toshiba Electronic Devices & Storage Corporation, Kawasaki-shi (JP)

(72) Inventor: Fumiyoshi Kawashiro, Tokyo (JP)

(21) Appl. No.: 19/305,627

(22) Filed: Aug. 20, 2025

(30) Foreign Application Priority Data
Sep. 11, 2024 (JP) 2024-157597

(51) Int. Cl. H10D 80/20; H01L 23/00; H01L 23/31; H01L 23/373; H01L 25/00; H01L 25/07

(52) U.S. Cl. CPC H10D 80/251; H10W 40/255; H10W 74/127; H10W 90/00; H10W 72/634; H10W 90/734; H10W 90/764

(57) ABSTRACT

According to one embodiment, a semiconductor apparatus includes: a wiring board having a first through-hole; a first substrate including a first conductive layer, a first insulating layer on the first conductive layer, and a second conductive layer on the first insulating layer, the first substrate being provided in the first through-hole; a first semiconductor chip provided on the first substrate in the first through-hole; and a sealing member that covers the first substrate and the first semiconductor chip in the first through-hole, wherein a first dimension of the first insulating layer in a first direction parallel to a surface of the first substrate is larger than a second dimension of the first conductive layer in the first direction and a third dimension of the second conductive layer in the first direction.

### CROSS-REFERENCE TO RELATED APPLICATIONS

This application is based upon and claims the benefit of priority from prior Japanese Patent Application No. 2024-157597, filed Sep. 11, 2024, the entire contents of which are incorporated herein by reference.

### FIELD

Embodiments described herein relate generally to a semiconductor apparatus.

### BACKGROUND

Development of a semiconductor apparatus as a power module has been promoted.

### BRIEF DESCRIPTION OF DRAWINGS

FIG. 1 is a bird's-eye view schematically illustrating a structure of a semiconductor apparatus of a first embodiment.

FIG. 2 is a circuit diagram illustrating a circuit configuration of the semiconductor apparatus of the first embodiment.

FIG. 3 is a plan view illustrating a structure example of the semiconductor apparatus of the first embodiment.

FIG. 4 is a sectional view illustrating the structure example of the semiconductor apparatus of the first embodiment.

FIG. 5 is a sectional view illustrating the structure example of the semiconductor apparatus of the first embodiment.

FIG. 6 is a sectional view illustrating the structure example of the semiconductor apparatus of the first embodiment.

FIG. 7 is a flowchart illustrating a method for manufacturing the semiconductor apparatus of the first embodiment.

FIG. 8 is a plan view illustrating a structure example of the semiconductor apparatus of a second embodiment.

FIG. 9 is a sectional view illustrating the structure example of the semiconductor apparatus of the second embodiment.

FIG. 10 is a sectional view illustrating the structure example of the semiconductor apparatus of the second embodiment.

FIG. 11 is a sectional view illustrating the structure example of the semiconductor apparatus of the second embodiment.

FIG. 12 is a sectional view illustrating a structure example of the semiconductor apparatus of a third embodiment.

### DETAILED DESCRIPTION

In general, according to one embodiment, a semiconductor apparatus includes: a wiring board having a first through-hole; a first substrate including a first conductive layer, a first insulating layer on the first conductive layer, and a second conductive layer on the first insulating layer, the first substrate being provided in the first through-hole; a first semiconductor chip provided on the first substrate in the first through-hole; and a sealing member that covers the first substrate and the first semiconductor chip in the first through-hole, wherein a first dimension of the first insulating layer in a first direction parallel to a surface of the first substrate is larger than a second dimension of the first conductive layer in the first direction and a third dimension of the second conductive layer in the first direction.

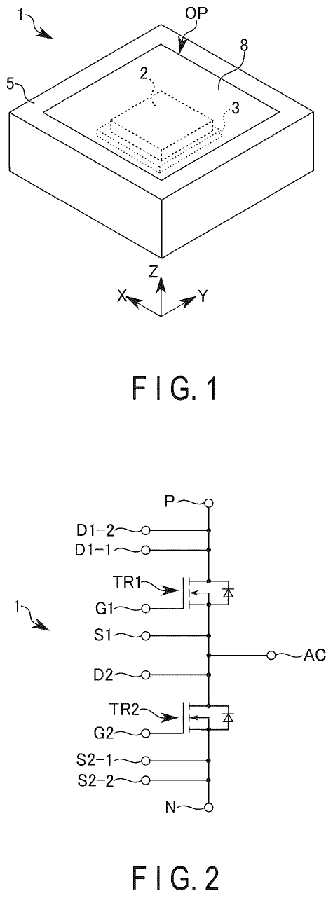

A semiconductor apparatus of an embodiment will be described with reference to FIGS. 1 to 12. In the following description, components having substantially the same function and configuration are denoted by the same reference numerals. Further, in each of the following embodiments, in a case where the components (for example, circuits, wirings, various voltages and signals, and the like) with reference numerals suffixed with numbers/letters at the end for distinguishing are not necessarily distinguished from each other, a description (reference numeral) in which the numerals/letters at the end are omitted is used.

### EMBODIMENTS

### (1) First Embodiment

A semiconductor apparatus according to a first embodiment will be described with reference to FIGS. 1 to 7.

### (a) Configuration Example

FIG. 1 is a bird's-eye view schematically illustrating a semiconductor apparatus 1 of the first embodiment.

As illustrated in FIG. 1, the semiconductor apparatus 1 of the present embodiment includes a wiring board 5, a semiconductor chip 2, a substrate 3, and a sealing member 8.

The wiring board 5 is a board including wiring (not illustrated). The wiring is provided on a surface of the wiring board 5. The wiring board 5 has a through-hole OP.

The substrate 3 is a substrate including an insulating layer. The substrate 3 is provided in the through-hole OP of the wiring board 5. A back surface of the substrate 3 is exposed through the through-hole OP.

The semiconductor chip 2 is a chip including one or more semiconductor elements. The semiconductor chip 2 is provided on a surface of the substrate 3. The semiconductor chip 2 is embedded in the through-hole OP of the wiring board 5 together with the substrate 3.

A sealing member 8 is provided in the through-hole OP. The sealing member 8 covers the semiconductor chip 2 and the substrate 3 in the through-hole OP.

As described above, in the semiconductor apparatus 1 of the present embodiment, the semiconductor chip 2 and the substrate 3 are built in the wiring board 5.

FIG. 2 is a circuit diagram illustrating a circuit configuration of the semiconductor apparatus 1 of the first embodiment.

The semiconductor apparatus 1 of the present embodiment is a power module. For example, the semiconductor apparatus 1 includes a half-bridge circuit.

As illustrated in FIG. 2, the semiconductor apparatus 1 includes transistors TR1 and TR2 and terminals P, N, AC, D1-1, D1-2, D2, S1, S2-1, S2-2, G1, and G2.

Each of the terminal P and the terminal N is a power supply terminal of the semiconductor apparatus 1. A positive power supply voltage is applied to the terminal P. A negative power supply voltage (or a ground voltage) is applied to the terminal N.

The terminal AC is an output terminal of the semiconductor apparatus 1.

Each of the terminal G1 and the terminal G2 is a control terminal of the semiconductor apparatus 1.

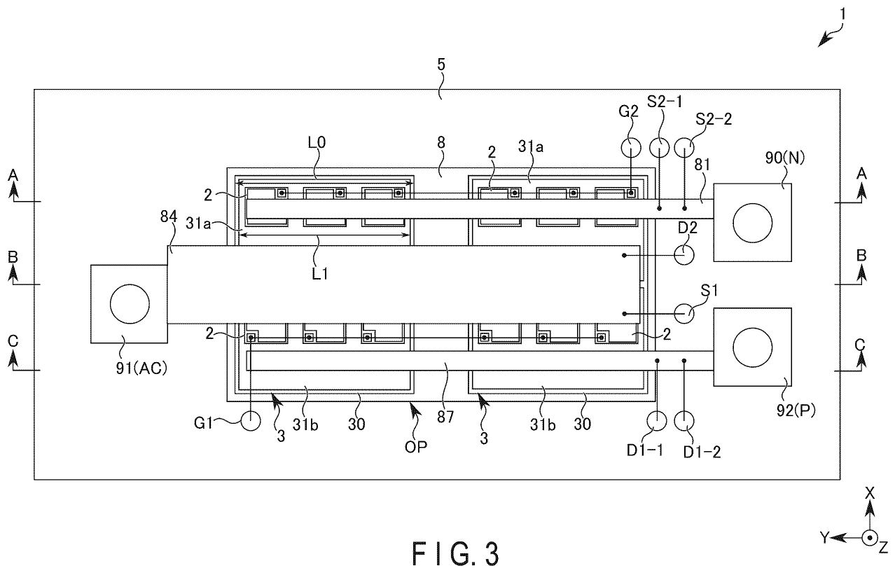

Each of the transistor TR1 and the transistor TR2 is, for example, an N-type vertical MOS transistor using silicon or silicon carbide. Although the vertical MOS transistor is illustrated in FIG. 3, the transistors TR1 and TR2 may be vertical insulated gate bipolar transistors (IGBTs) or transistors using gallium nitride.

Between the terminal P and the terminal N, a current path of the transistor TR1 is connected in series to a current path of the transistor TR2.

A drain of the transistor TR1 is connected to the terminal P. A source of the transistor TR1 is connected to the terminal AC. A gate of the transistor TR1 is connected to the terminal G1.

A drain of the transistor TR2 is connected to the terminal AC. A source of the transistor TR2 is connected to the terminal N. A gate of the transistor TR2 is connected to the terminal G2.

For example, each of the transistors TR1 and TR2 may include a plurality of transistors connected in parallel to each other or a plurality of transistors connected in series to each other.

Each of the terminals D1-1, D1-2, D2, S1, S2-1, and S2-2 is a terminal for monitoring an operation of the semiconductor apparatus 1. The terminals D1-1 and D1-2 are connected to the drain of the transistor TR1. The terminal S1 is connected to the source of the transistor TR1. The terminal D2 is connected to the drain of the transistor TR2. The terminals S2-1 and S2-2 are connected to the source of the transistor TR2.

With the configuration of FIG. 2, semiconductor elements TR1 and TR2 inside the semiconductor apparatus 1 can be controlled by a voltage supplied from outside the semiconductor apparatus 1.

A structure example of the semiconductor apparatus 1 of the present embodiment will be described with reference to FIGS. 3 to 6.

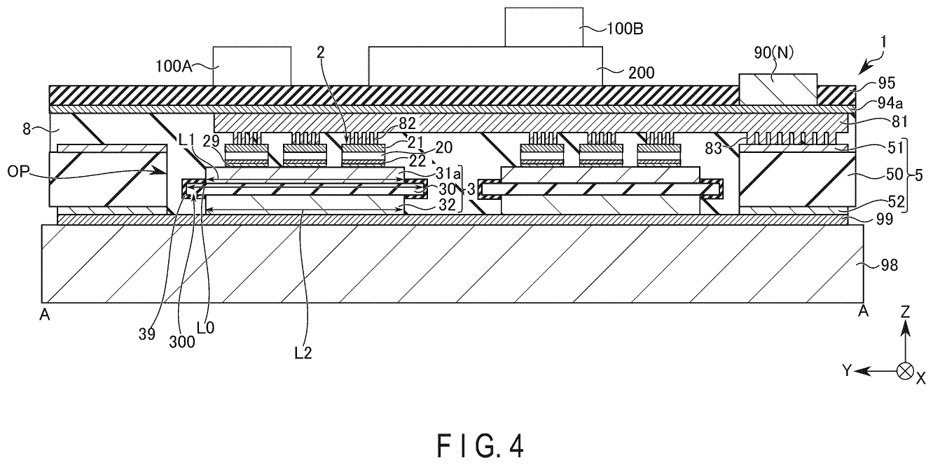

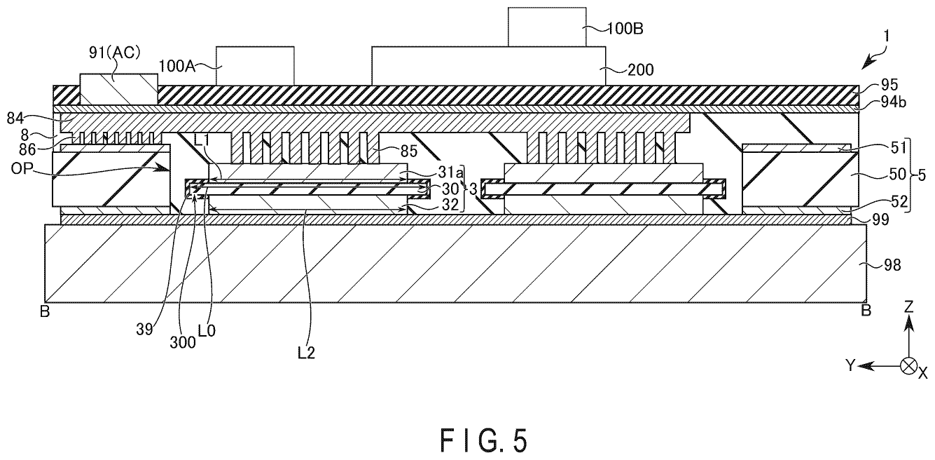

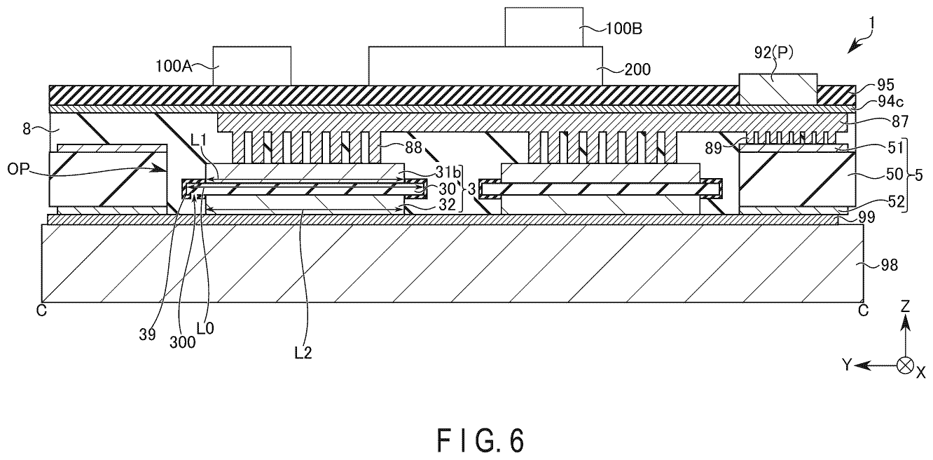

FIG. 3 is a plan view illustrating a structure example of the semiconductor apparatus 1 of the present embodiment. FIGS. 4 to 6 are sectional views illustrating the structure example of the semiconductor apparatus 1 of the present embodiment. FIG. 4 illustrates a section taken along line A-A in FIG. 3. FIG. 5 illustrates a section taken along line B-B in FIG. 3. FIG. 6 illustrates a section taken along line C-C in FIG. 3.

As illustrated in FIGS. 3 to 6, the semiconductor apparatus 1 of the present embodiment includes the wiring board 5, one or more semiconductor chips 2, the substrate 3, and the sealing member 8.

The wiring board 5 is, for example, a printed wiring board. The wiring board 5 includes a core member 50 and conductive layers 51 and 52.

The core member (also referred to as a first wall) 50 has the through-hole OP. The core member 50 has a quadrangular annular structure as viewed from a direction perpendicular to a main surface of the wiring board 5. The core member 50 is a wall surrounding a space in which the semiconductor chip 2 is provided. The core member 50 is an insulating member. For example, the core member 50 includes a material including a sealing resin such as an epoxy resin. As a specific example, the core member 50 is a mixture of epoxy resin and glass fiber.

The conductive layers 51 and 52 are respectively provided on a front surface and a back surface of the core member 50. The conductive layer 51 is used as a wiring or a terminal for connecting the semiconductor chip 2 and a device outside the semiconductor apparatus 1. The conductive layer 52 is used as, for example, a wiring or a heat sink. The conductive layers 51 and 52 are, for example, metal layers including copper (Cu). The conductive layer 51 may be connected to the conductive layer 52 with a plug (not illustrated) formed in the core member 50 interposed therebetween.

The semiconductor chip 2 and the substrate 3 are embedded in the through-hole OP of the wiring board 5. Six semiconductor chips 2 are provided on one substrate 3. 12 semiconductor chips 2 and two substrates 3 are provided in the through-hole OP.

The semiconductor chip 2 includes a semiconductor element 20 and conductive layers 21 and 22. In the semiconductor chip 2, the semiconductor element 20 is sandwiched between the conductive layers 21 and 22. The semiconductor element 20 is, for example, a vertical transistor. The conductive layer 21 is provided on a front surface (an upper surface) of the semiconductor chip. The conductive layer 22 is provided on a back surface (a lower surface) of the semiconductor chip. In a case where the semiconductor element 20 is the vertical MOS field effect transistor (MOSFET), the conductive layer 21 is a source electrode plate of the transistor, and the conductive layer 22 is a drain electrode plate of the transistor.

The conductive layer 21 is a layer including copper. A thickness (dimension in a Z direction) of the conductive layer 21 is 10 μm or more. For example, the conductive layer 21 is desirably 20 μm or more. In a case where the conductive layer 21 is a copper layer, for example, the conductive layer 21 is formed by plating. Thus, a transient thermal behavior of the semiconductor element of the semiconductor chip 2 is improved.

The conductive layer 22 is a layer including any one of gold (Au), silver (Ag), and a gold-silver alloy. The conductive layer 22 may be a layer including copper.

A conductor 29 is provided between the conductive layer 22 and the substrate 3. The conductor 29 includes a sintered material such as pressurized silver or a solder material. In a case where an active sintered material is used for the conductor 29, an oxide film on a surface of a copper layer can be removed.

The semiconductor chip 2 is connected to a conductive layer (wiring) 31 (31a, 31b) on the substrate 3 with the conductive layer 22 and the conductor 29 interposed therebetween. Thus, a plurality of semiconductor chips 2 are electrically connected to each other. Note that the semiconductor chips 2 may be connected to the conductive layer 31 by a bonding wire.

A first set of six semiconductor chips 2 arranged in a Y direction is connected to a conductive layer 81 with the conductive layer 21 and a plug 82 interposed therebetween. The conductive layer 81 is connected to the conductive layer 51 of the wiring board 5 with a plug 83 interposed therebetween. Thus, the semiconductor chips 2 are electrically connected to the wiring board 5.

In the through-hole OP of the wiring board 5, the two substrates 3 are arranged in the Y direction. The sealing member 8 is provided between the two substrates 3.

The substrate 3 includes an insulating layer 30 and conductive layers 31a, 31b, and 32. The conductive layers 31a and 31b are provided on a front surface of the insulating layer 30. The conductive layer 31a is separated from the conductive layer 31b. The conductive layer 31a is aligned with the conductive layer 31b in an X direction. The conductive layer 32 is provided under a back surface of the insulating layer 30. The insulating layer 30 is sandwiched between the two conductive layers 31 (31a and 31b) and 32. A back surface of the conductive layer 32 is exposed through the through-hole OP.

The conductive layers 31a and 31b are used as wirings. The conductive layer 32 is used as a heat sink. The conductive layers 31a, 31b, and 32 are, for example, copper layers. For example, a film thickness (dimension in the Z direction) of the conductive layers 31a, 31b, and 32 is 0.3 mm or more. The film thickness of the conductive layers 31a, 31b, and 32 is desirably 1.0 mm or more.

The conductive layer 31a is connected to a conductive layer 84 with a plug 85 interposed therebetween. The conductive layer 84 is connected to the conductive layer 51 of the wiring board 5 with a plug 86 interposed therebetween. Thus, the semiconductor chips 2 are electrically connected to the wiring board 5. In addition, the conductive layer 84 is connected to a second set of six semiconductor chips 2 arranged in the Y direction with a plug (not illustrated) interposed therebetween.

The conductive layer 31b is connected to a conductive layer 87 with a plug 88 interposed therebetween. The conductive layer 87 is connected to the conductive layer 51 of the wiring board 5 with a plug 89 interposed therebetween. Thus, the semiconductor chips 2 are electrically connected to the wiring board 5.

The insulating layer 30 is, for example, a silicon nitride layer (SiN layer). The insulating layer 30 including (containing) silicon nitride has high fracture toughness and good thermal conductivity. Since the insulating layer 30 has high fracture toughness, a film thickness of copper used for the conductive layer (wiring) 31 of the substrate 3 can be increased. Since the insulating layer 30 has high thermal conductivity, heat generated from the semiconductor chip 2 can be dissipated.

For example, a film thickness of the insulating layer 30 including silicon nitride is about 0.25 mm to 0.5 mm. Thus, in a case where a high voltage of about 1200 V to 3300 V is applied to the semiconductor apparatus 1, it is possible to prevent the semiconductor chip 2 and the semiconductor apparatus 1 from being dielectrically broken down. For example, the film thickness (dimension in the Z direction) of the insulating layer 30 is thicker than those of the conductive layers 31 and 32.

In a case where the insulating layer 30 including silicon nitride has a structure sandwiched between the conductive layers 31 and 32, influence of parasitic impedance (for example, parasitic inductance) of the substrate 3 is reduced. Accordingly, the substrate 3 has excellent electromagnetic interference (EMI) characteristics. For example, influence of reduction in inductance is effective in reducing surge voltage generated in the semiconductor apparatus 1.

Ends (hereinafter, referred to as side portions or protrusions) 300 in the X direction and the Y direction of the insulating layer 30 protrude in the X direction and the Y direction from ends in the X direction and the Y direction of the conductive layers 31 and 32.

A dimension L0 of the insulating layer 30 in the Y direction is larger than a dimension L1 of the conductive layer 31 in the Y direction and a dimension L2 of the conductive layer 32 in the Y direction. The substrate 3 has a structure in which the side portions of the insulating layer 30 protrude from side portions of the conductive layers 31 and 32. Thus, the insulating layer 30 cuts off a line of electric force generated between the conductive layers 31 and 32. As a result, in the semiconductor apparatus 1 of the present embodiment, the insulating layer 30 can prevent leakage between the conductive layers 31 and 32 bypassing the side portions of the insulating layer 30.

A dimension of the insulating layer 30 in the X direction is larger than that of the conductive layer 31 in the X direction (however, a sum of dimensions of the two conductive layers 31a and 31b in the X direction) and that of the conductive layer 32 in the X direction. In a case where the dimension of the insulating layer 30 is larger than those of the conductive layers 31 and 32, the dimension of the insulating layer 30 in the X direction may be different from the dimension of the insulating layer 30 in the Y direction.

An area of the insulating layer 30 viewed from the Z direction is larger than a sum of areas of the conductive layers 31a and 31b viewed from the Z direction and is larger than an area of the conductive layer 32 viewed from the Z direction.

The side portions 300 of the insulating layer 30 are covered with a coating film 39. The coating film 39 covers an upper surface, a side surface, and a lower surface of the side portion 300. The coating film 39 is a film including an insulator. The coating film 39 functions as an adhesion-imparting material between the insulating layer 30 and the sealing member 8. The coating film 39 improves adhesion between the insulating layer 30 and the sealing member 8. The coating film 39 suppresses destruction of the insulating layer 30 due to heat and/or a high voltage.

The sealing member 8 is provided on the wiring board 5. The sealing member 8 is embedded in the through-hole OP in the wiring board 5. The sealing member 8 is provided between the wiring board 5 and the semiconductor chip 2, between the semiconductor chips 2, between the two substrates 3, and between the wiring board 5 and the substrate 3. The sealing member 8 is an insulator formed of resin such as prepreg or epoxy.

The conductive layers 81, 84, and 87 are provided on the front surface side of the wiring board 5. The conductive layers 81, 84, and 87 are embedded in the sealing member 8.

The conductive layer 81 is connected to a terminal 90 with a conductor 94a such as the solder material or the sintered material interposed therebetween. The terminal 90 is, for example, the terminal N to which the negative (or 0 V) power supply voltage is applied. For example, the terminals S2-1 and S2-2 are connected to the conductive layer 81.

The conductive layer 84 is connected to a terminal 91 with a conductor 94b such as the solder material or the sintered material interposed therebetween. The terminal 91 is, for example, an output terminal AC of the semiconductor apparatus 1.

The conductive layer 87 is connected to a terminal 92 with a conductor 94c such as the solder material or the sintered material interposed therebetween. The terminal 92 is, for example, the terminal P to which the positive power supply voltage is applied.

An insulating layer 95 covers the conductive layers 81, 84, and 87 and the conductors 94a, 94b, and 94c. The terminals 90, 91, and 92 are embedded in an opening of the insulating layer 95.

The terminals D2 and S1 are connected to the conductive layer 84. The terminals D1-1 and D1-2 are connected to the conductive layer 87. The terminals G1 and G2 are connected to gates of the corresponding semiconductor chips 2.

For example, a dimension of the semiconductor apparatus 1 of the present embodiment in the Z direction is about 2 mm.

For example, the semiconductor apparatus 1 is provided on a heat dissipation mechanism 98. The heat dissipation mechanism 98 is provided on a back surface side of the wiring board 5. In the semiconductor apparatus 1, the conductive layer 32 exposed on the back surface side of the substrate 3 is bonded to the heat dissipation mechanism 98 with an adhesive layer 99 such as the sintered material or the solder material interposed therebetween. The heat dissipation mechanism 98 is a heat sink 98. The heat sink 98 is, for example, a copper plate. Note that the heat dissipation mechanism 98 may be a cooler.

For example, components 100A and 100B and another semiconductor apparatus 200 may be stacked on the semiconductor apparatus 1 by surface mounting. The component 100A and the semiconductor apparatus 200 are provided on the insulating layer 95. The component 100B is provided on the semiconductor apparatus 200. The components 100A and 100B are, for example, passive elements such as capacitors. The semiconductor apparatus 200 is, for example, a gate drive circuit. This makes it possible to provide a semiconductor module (for example, a power module) including the semiconductor apparatus 1 of the present embodiment.

### (b) Manufacturing Method

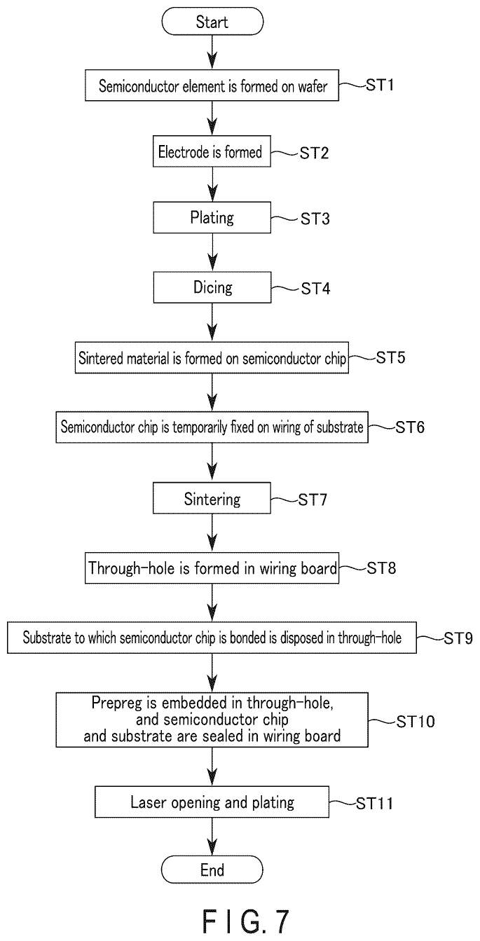

A method for manufacturing the semiconductor apparatus of the present embodiment will be described with reference to FIG. 7.

FIG. 7 is a flowchart for explaining the method for manufacturing the semiconductor apparatus 1 of the present embodiment.

### (Step ST1)

The semiconductor element 20 such as a transistor is formed in each of chip areas of a wafer by a well-known technique.

### (Step ST2)

An electrode is formed on the semiconductor element.

### (Step ST3)

Plating is performed on the wafer. Thus, the conductive layer 21 including copper is formed on the electrode of the semiconductor element.

### (Step ST4)

Dicing of the wafer is performed. Thus, the semiconductor chips 2 are formed from the wafer. Note that a thickness of the wafer may be ground to a desired thickness before dicing the wafer.

### (Step ST5)

A sintered material 29 is formed under the back surface of the semiconductor chip 2 or on the conductive layer 31. The sintered material 29 has conductivity.

### (Step ST6)

The semiconductor chip 2 is temporarily fixed on the conductive layer 31 of the substrate 3 with the sintered material 29 interposed therebetween.

### (Step ST7)

Sintering is performed on the substrate 3 on which the semiconductor chip 2 is disposed. Thus, the sintered material 29 is sintered. The semiconductor chip 2 is bonded (fixed) onto the substrate 3 by sintering the sintered material 29. The semiconductor chip 2 is electrically connected to the conductive layer 31 of the substrate 3 with the sintered material (conductor) 29 interposed therebetween. In a case where the sintered material 29 having activity is bonded to the conductive layer 31 including copper, an oxide film on a surface of the conductive layer 31 is removed by the sintered material 29.

### (Step ST8)

The through-hole OP is formed in the wiring board 5 on which the conductive layers 51 and 52 are formed.

### (Step ST9)

The substrate 3 to which the semiconductor chip 2 is bonded is disposed in the through-hole OP of the wiring board 5.

### (Step ST10)

The prepreg is embedded in the through-hole OP. The prepreg is cured by heat treatment and pressure treatment. Thus, the semiconductor chip 2 and the substrate 3 in the through-hole OP are sealed in the wiring board 5 by the cured prepreg (sealing member) 8.

### (Step ST11)

An opening or a groove is formed in the sealing member 8 of the prepreg by laser processing. Thereafter, the conductive layers 81, 84, and 87 and the plugs 82,83,85,86,88, and 89 are formed on (in) the sealing member 8 by plating.

Thereafter, the conductors 94a, 94b, and 94c such as the solder material or the sintered material and the insulating layer 95 are formed on the wiring board 5 and the conductive layers 81,84, and 87. The terminals 90,91, and 92 are respectively connected to the corresponding conductive layers 81,84, and 87.

For example, the components 100A and 100B and the other semiconductor apparatus 200 are mounted on the semiconductor apparatus 1 by surface mounting.

Through the above manufacturing process, the semiconductor apparatus 1 of the present embodiment is completed.

### (c) Summary

The semiconductor apparatus 1 of the present embodiment has a structure in which the semiconductor chips 2 arranged on the insulating substrate 3 is sealed by the sealing member 8 in the through-hole OP in the wiring board 5.

In the semiconductor apparatus 1 of the present embodiment, the insulating substrate 3 has a structure in which the insulating layer 30 of silicon nitride is sandwiched between the two conductive layers (for example, copper layers) 31 and 32.

In the present embodiment, the dimension L0 of the insulating layer 30 in the X direction (or the Y direction) is larger than the dimension L1 of the conductive layer 31 in the X direction (or the Y direction) and the dimension L2 of the conductive layer 32 in the X direction (or the Y direction). In the present embodiment, the insulating substrate 3 has the structure in which the side portions of the insulating layer 30 protrude from the side portions of the conductive layers 31 and 32. Thus, the insulating layer 30 can cut off an electrical connection between the conductive layers 31 and 32 bypassing the side portions of the insulating layer 30. Therefore, the semiconductor apparatus 1 of the present embodiment can secure a margin that reaches creeping discharge between the conductive layers 31 and 32 in the substrate 3.

The semiconductor apparatus 1 of the present embodiment can achieve weight reduction, high voltage resistance, high output, and high efficiency of the power module by the above-described configuration.

As a result, in a case where the semiconductor apparatus 1 of the present embodiment is used as the power module of an electric vehicle, a battery voltage (charging output) can be increased. Therefore, the semiconductor apparatus 1 of the present embodiment can shorten a charging period of the electric vehicle.

In addition, according to the present embodiment, by making a charging cable thinner, lighter, and higher in voltage, generation of a current at the time of charging using the power module including the semiconductor apparatus 1 of the present embodiment is suppressed. Thus, the semiconductor apparatus 1 of the present embodiment can reduce a heat generation amount of a cable of the power module and simplify a cooling mechanism. As described above, the semiconductor apparatus 1 of the present embodiment can realize simplification and cost reduction of a system using the semiconductor apparatus 1 of the present embodiment.

The semiconductor apparatus 1 of the present embodiment can improve power performance of the electric vehicle by achieving the high output and the high efficiency. The semiconductor apparatus 1 of the present embodiment can achieve high output of a drive motor while achieving downsizing and weight reduction of the drive motor by thinning the cable.

As described above, the semiconductor apparatus of the present embodiment can improve characteristics of the semiconductor apparatus.

### (2) Second Embodiment

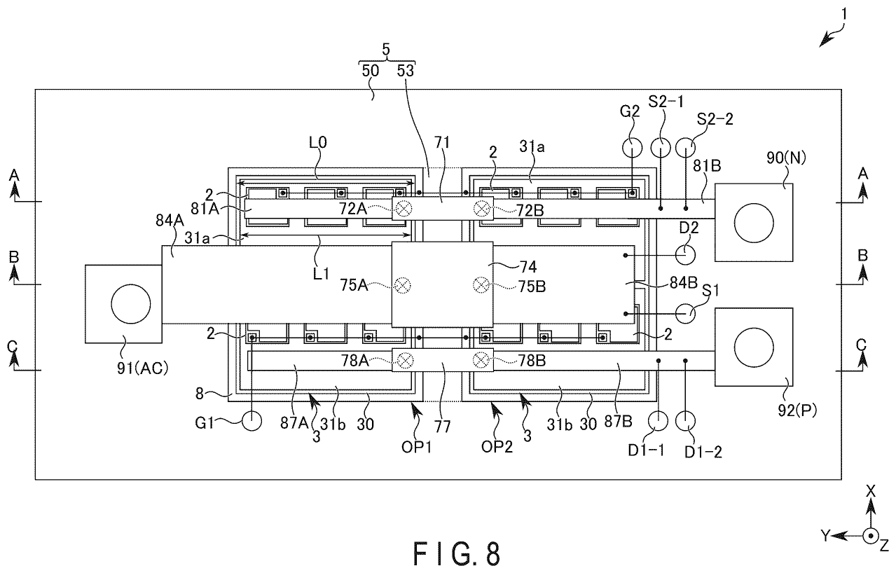

The semiconductor apparatus according to a second embodiment will be described with reference to FIGS. 8 to 11.

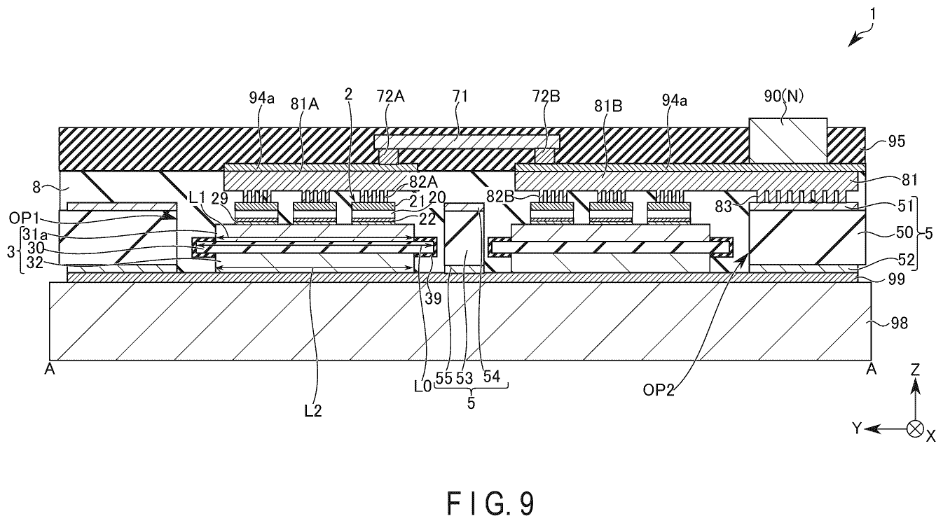

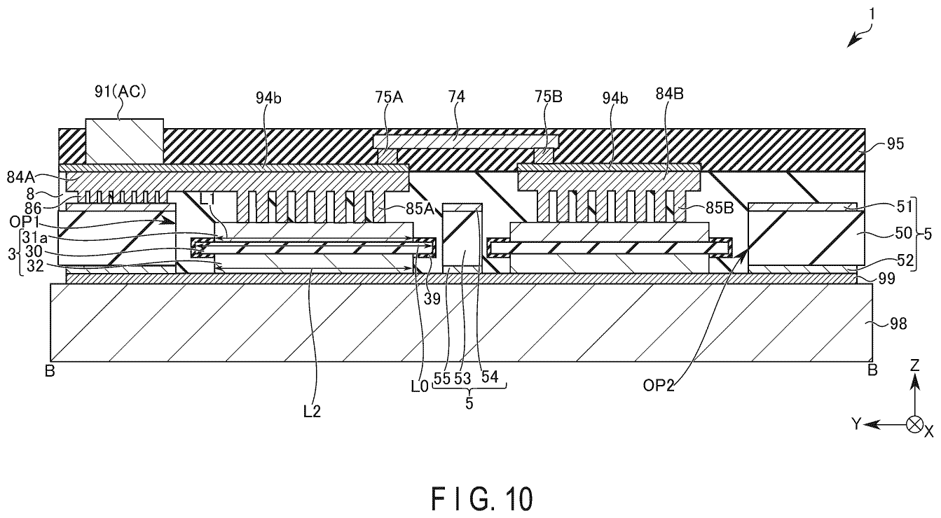

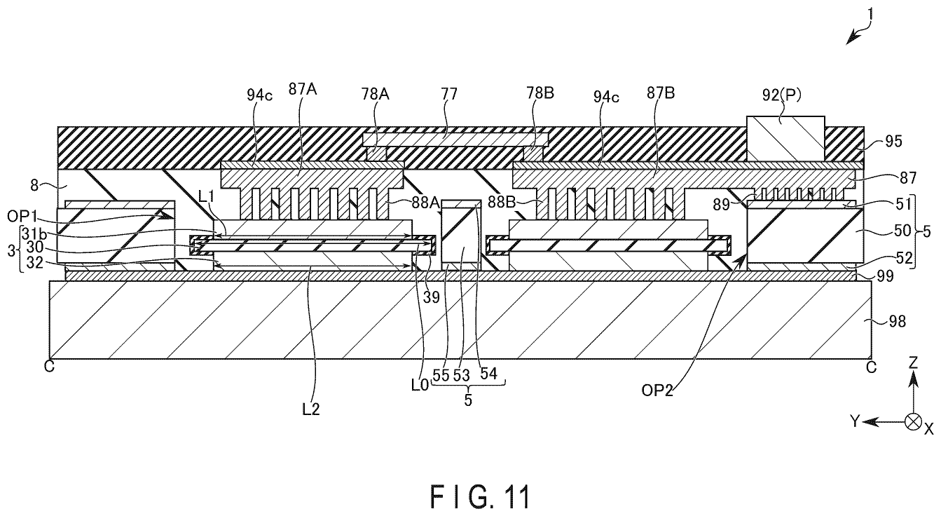

FIG. 8 is a plan view illustrating the structure example of the semiconductor apparatus 1 of the present embodiment. FIGS. 9 to 11 are sectional views illustrating the structure example of the semiconductor apparatus 1 of the present embodiment. FIG. 9 illustrates a section taken along line A-A in FIG. 8. FIG. 10 illustrates a section taken along line B-B in FIG. 8. FIG. 11 illustrates a section taken along line C-C in FIG. 8.

The wiring board 5 may include two through-holes OP1 and OP2.

The two through-holes OP1 and OP2 are separated by a core member 53. The through-holes OP1 and OP2 are arranged in the Y direction with the core member 53 interposed therebetween. Hereinafter, the core member 53 between the through-holes OP1 and OP2 is referred to as a separation portion 53 or a wall (second wall) 53.

The separation portion 53 is continuous with the core member 50. The separation portion 53 extends in a direction (for example, the X direction) intersecting a direction in which the through-holes OP1 and OP2 are arranged. The separation portion 53 is connected to a portion extending in the Y direction of the quadrangular annular core member 50. The separation portion 53 is a wall that separates the two through-holes OP1 and OP2.

The conductive layer 54 is provided on a front surface of the separation portion 53. The conductive layer 54 is continuous with the conductive layer 51 or separated from the conductive layer 51 depending on a layout of the wiring.

The conductive layer 55 is provided under a back surface of the separation portion 53. The conductive layer 55 is, for example, continuous with the conductive layer 52. However, the conductive layer 55 may be separated from the conductive layer 52.

One semiconductor chip 2 and one substrate 3 are provided in one through-hole OP1. The other semiconductor chip 2 and the other substrate 3 are provided in the other through-hole OP2. The separation portion 53 is provided between the two substrates 3.

A conductive layer 81A is connected to the one semiconductor chip 2 with a plug 82A interposed therebetween. A conductive layer 81B is connected to the other semiconductor chip 2 with a plug 82B interposed therebetween. The conductive layer 81A is connected to the conductive layer 81B with a conductive layer 71 and plugs 72A and 72B (and the conductor 94a) interposed therebetween.

A conductive layer 84A is connected to the conductive layer 31a on the one substrate 3 with a plug 85A interposed therebetween. A conductive layer 84B is connected to the conductive layer 31a on the other substrate 3 with a plug 85B interposed therebetween. The conductive layer 84A is connected to the conductive layer 84B with a conductive layer 74 and plugs 75A and 75B (and the conductor 94b) interposed therebetween.

A conductive layer 87A is connected to the conductive layer 31b on the one substrate 3 with a plug 88A interposed therebetween. A conductive layer 87B is connected to the conductive layer 31b on the other substrate 3 with a plug 88B interposed therebetween. The conductive layer 87A is connected to the conductive layer 87B with a conductive layer 77 and plugs 78A and 78B (and the conductor 94c) interposed therebetween.

The conductive layers 71, 74, and 77 and the plugs 72A, 72B, 75A, 75B, 78A, and 78B are provided in the insulating layer 95 on the wiring board 5. Each of the conductive layers 71, 74, and 77 extends from the one through-hole OP1 side to the other through-hole OP2 side through above the separation portion 53. The conductive layers 71, 74, and 77 may be exposed from the insulating layer 95.

Note that three or more through-holes OP may be provided in the wiring board 5 by two or more separation portions 53.

In the present embodiment, at the time of ultrasonic bonding of the terminals 90, 91, and 92 to the semiconductor chip 2 and the substrate 3 in the one through-hole OP1, the separation portion 53 suppresses propagation of an impact caused by an ultrasonic wave to the semiconductor chip 2 and the substrate 3 in the other through-hole OP2.

In the present embodiment, rigidity of the wiring board 5 having the through-hole OP is increased by providing the separation portion 53.

Thus, the semiconductor apparatus 1 of the present embodiment can prevent destruction of the semiconductor chip 2 and peeling of the conductive layers 31 and 32.

As a result, the semiconductor apparatus 1 of the present embodiment can reduce defects of the semiconductor apparatus.

### (3) Third Embodiment

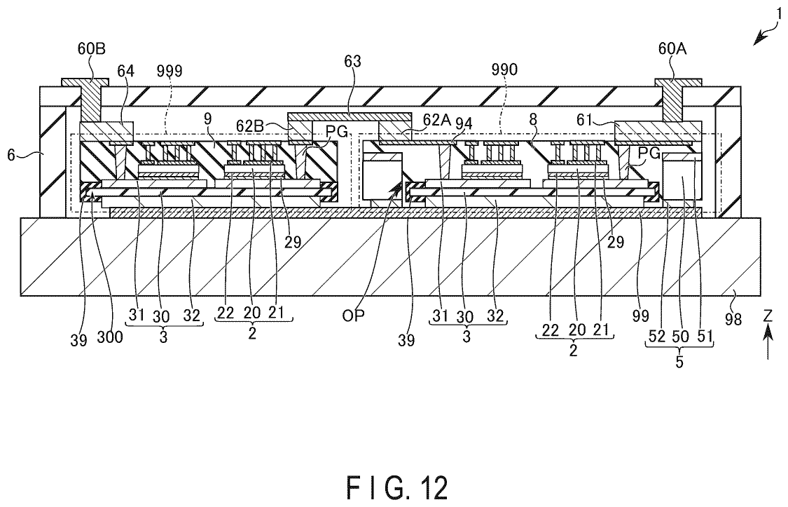

The semiconductor apparatus according to a third embodiment will be described with reference to FIG. 12.

FIG. 12 is a sectional view illustrating the structure example of the semiconductor apparatus 1 of the present embodiment.

As illustrated in FIG. 12, the semiconductor apparatus 1 of the present embodiment may include a device 990 including the semiconductor chip 2 embedded in the wiring board 5, and a device 999 including the semiconductor chip 2 provided in a semiconductor package 9. The semiconductor package 9 including the semiconductor chip 2 is provided on one heat sink 98 together with the wiring board 5 in which the semiconductor chip 2 is embedded.

In the semiconductor apparatus 1 of the present embodiment, the semiconductor chip 2 and the substrate 3 are built in the through-hole OP of the wiring board 5.

The substrate 3 including the silicon nitride layer 30 may not be built in the through-hole OP of the wiring board 5.

The semiconductor package 9 covers the semiconductor chip 2 on the substrate 3. The semiconductor package 9 is an insulating sealing member (for example, a resin). A plug PG is provided in the semiconductor package 9. In the substrate 3, the side portions 300 of the insulating layer 30 protrude from the ends of the conductive layers 31 and 32. The dimension of the insulating layer 30 in a direction parallel to the surface of the wiring board 5 is larger than that of the conductive layer 31 in the direction parallel to the surface of the wiring board 5 (a sum of dimensions in a direction in which two conductive layers 31 on the same substrate 3 are arranged) and that of the conductive layer 32 in the direction parallel to the surface of the wiring board 5.

The semiconductor chip 2 in the semiconductor package 9 is electrically connected to the semiconductor chip 2 in the wiring board 5 with the plug PG, conductors 62A and 62B, and wiring 63 interposed therebetween.

The conductive layer 31 of the substrate 3 in the semiconductor package 9 is connected to a terminal 60B with the plug PG and a conductor 64 interposed therebetween.

In the substrate 3 in the through-hole OP of the wiring board 5, the conductive layer 31 of the substrate 3 is connected to a terminal 60A with the plug PG in the sealing member 8 and a conductor 61 interposed therebetween.

The semiconductor package 9 including the semiconductor chip 2 and the wiring board 5 incorporating the semiconductor chip 2 may be provided in a case (housing) 6. The terminals 60A and 60B are exposed from the case 6.

Note that the device 999 including the semiconductor chip 2 on the substrate 3 sealed by the semiconductor package 9 may be provided as one semiconductor device 999.

The semiconductor apparatus 1 of the present embodiment can obtain substantially the same effects as those of the above-described embodiment.

### (4) Others

In the above-described embodiments, an example in which the semiconductor apparatus 1 of the embodiment is used for a DC-DC converter is shown. However, the semiconductor apparatus 1 of the embodiments may be applied to another semiconductor circuit such as an inverter.

The semiconductor apparatus 1 of the embodiments can be applied to the electric vehicle, a railway vehicle, a household electrical appliance, a power system, and the like.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor apparatus comprising:
a wiring board having a first through-hole;
a first substrate including a first conductive layer, a first insulating layer on the first conductive layer, and a second conductive layer on the first insulating layer, the first substrate being provided in the first through-hole;
a first semiconductor chip provided on the first substrate in the first through-hole; and
a sealing member that covers the first substrate and the first semiconductor chip in the first through-hole, wherein
a first dimension of the first insulating layer in a first direction parallel to a surface of the first substrate is larger than a second dimension of the first conductive layer in the first direction and a third dimension of the second conductive layer in the first direction.

2. The semiconductor apparatus according to claim 1, wherein the first insulating layer includes silicon nitride.

3. The semiconductor apparatus according to claim 1, further comprising a first film provided between the sealing member and the first insulating layer and covering a side portion of the first insulating layer.

4. The semiconductor apparatus according to claim 1, further comprising:
a second substrate; and
a second semiconductor chip provided on the second substrate, wherein
the wiring board further includes a second through-hole and a separation portion between the first through-hole and the second through-hole, and
the second substrate and the second semiconductor chip are provided in the second through-hole.

5. The semiconductor apparatus according to claim 4, further comprising a third conductive layer that connects the first semiconductor chip to the second semiconductor chip through above the separation portion.

6. The semiconductor apparatus according to claim 1, further comprising:
a heat dissipation mechanism in which the wiring board is provided; and
a semiconductor package that is provided on the heat dissipation mechanism, is adjacent to the wiring board in a direction parallel to a surface of the heat dissipation mechanism, and includes a third semiconductor chip.

7. The semiconductor apparatus according to claim 6, wherein
the third chip is provided on a third substrate,
the third substrate includes:
a fourth conductive layer;
a second insulating layer on the fourth conductive layer; and
a fifth conductive layer on the second insulating layer, and
a fourth dimension in the first direction of the second insulating layer is larger than a fifth dimension in the first direction of the fourth conductive layer and a sixth dimension in the first direction of the fifth conductive layer.

8. The semiconductor apparatus according to claim 1, further comprising a sixth conductive layer that is connected to the wiring board and the first semiconductor chip and provided in the sealing member.

9. The semiconductor apparatus according to claim 1, further comprising a heat dissipation mechanism bonded to a back surface of the second conductive layer exposed from the first through-hole.

10. The semiconductor apparatus according to claim 1, wherein the wiring board includes a first wall surrounding the first through-hole.

11. The semiconductor apparatus according to claim 10, wherein
the first wall includes:
a seventh conductive layer;
a third insulating layer provided on the seventh conductive layer; and
an eighth conductive layer on the third insulating layer.

12. A semiconductor apparatus comprising:
a substrate including a first conductive layer, an insulating layer on the first conductive layer, and a second conductive layer on the insulating layer;
a semiconductor chip provided on the substrate; and
an insulator that is provided on the substrate and covers the semiconductor chip, wherein
a first dimension of the insulating layer in a first direction parallel to a surface of the substrate is larger than a second dimension of the first conductive layer in the first direction and a third dimension of the second conductive layer in the first direction.

13. The semiconductor apparatus according to claim 12, wherein the insulating layer includes silicon nitride.

14. The semiconductor apparatus according to claim 12, wherein a second film covers a side portion of the insulating layer.

15. A semiconductor apparatus comprising:
a heat dissipation mechanism;
a first device provided on the heat dissipation mechanism; and
a second device provided on the heat dissipation mechanism, wherein
the first device includes:
a wiring board having a first wall surrounding a first through-hole;
a first substrate including a first conductive layer, a first insulating layer on the first conductive layer, and a second conductive layer on the first insulating layer, the first substrate being provided in the first through-hole;
a first semiconductor chip provided on the first substrate in the first through-hole; and
a first sealing member that covers the first substrate and the first semiconductor chip in the first through-hole, and
a first dimension of the first insulating layer in a first direction parallel to a surface of the first substrate is larger than a second dimension of the first conductive layer in the first direction and a third dimension of the second conductive layer in the first direction.

16. The semiconductor apparatus according to claim 15, wherein the first insulating layer includes silicon nitride.

17. The semiconductor apparatus according to claim 15, wherein the first device includes a first film provided between the sealing member and the first insulating layer and covering a side portion of the first insulating layer.

18. The semiconductor apparatus according to claim 15, wherein
the second device includes:
a second substrate including a third conductive layer, a second insulating layer on the third conductive layer, and a fourth conductive layer on the second insulating layer;
a second semiconductor chip provided on the second substrate; and
a second sealing member covering the second substrate and the second semiconductor chip.

19. The semiconductor apparatus according to claim 18, wherein a fourth dimension of the second insulating layer in the first direction is larger than a fifth dimension of the third conductive layer in the first direction and a sixth dimension of the fourth conductive layer in the first direction.

20. The semiconductor apparatus according to claim 18, wherein the second insulating layer includes silicon nitride.
